(19) United States
(12) Patent Application Publication
(10) Pub. No.: US 2017/0372989 A1
(43) Pub. Date: Dec. 28, 2017

(54) EXPOSED SIDE-WALL AND LGA ASSEMBLY

(71) Applicant: QUALCOMM Incorporated, San Diego, CA (US)

(72) Inventors: Daeik Daniel KIM, Del Mar, CA (US); Mario Francisco VELEZ, San Diego, CA (US); Changhan Hobie YUN, San Diego, CA (US); David Francis BERDY, San Diego, CA (US); Chengjie ZUO, San Diego, CA (US); Jonghae KIM, San Diego, CA (US)

(21) Appl. No.: 15/190,164

(22) Filed: Jun. 22, 2016

(51) Int. Cl. H01L 23/498; H01L 21/48; H01L 21/60; H01L 23/31

(52) U.S. Cl. CPC H01L 23/49805; H01L 21/4846; H01L 23/49811; H01L 2224/09155; H01L 2021/60007; H01L 23/3121; H01L 2224/16113; H01L 2224/16225; H01L 2224/081

(57) ABSTRACT

A device package with a reduced foot print may include a substrate and a through-substrate via extending from a top surface to a bottom surface of the substrate. The assembly may also include a trace and a contact pad on the top and bottom surfaces of the substrate and electrically coupled to the through-substrate via. An encapsulated die above the substrate may be electrically coupled to the trace. A joint below the substrate may be electrically coupled to the contact pad. A sidewall of the through-substrate via may be exposed. At least a portion of the through-substrate via may be within an outer side boundary of the substrate. Also, the trace and the contact pad may be within the outer side boundary of the substrate.

### FIELD OF DISCLOSURE

The field of the disclosed subject matter generally relates to device packages and to methods of manufacturing the device packages. In particular, the field of the disclosed subject matter relates to embedding of one or more dies in a substrate of a device package.

### BACKGROUND

In conventional die packages, land grid array (LGA) assemblies may be used. FIGS. 1A, 1B, and 1C respectively illustrate side, top, and bottom views of a conventional die package 100 such as a radio frequency (RF) module. FIG. 1B shows a horizontal dashed line bisecting the die package 100. FIG. 1A illustrates a cross-sectional view of the die package 100 along the horizontal dashed line of FIG. 1B.

As seen in these figures, the conventional die package 100 includes a substrate 160 with conductive vias 150 extending from a top surface to a bottom surface of the substrate 160. Traces 140, which are connected to the conductive vias 150, are formed on the top surface of the substrate 160. The die package 100 also includes a die 110 connected to the traces 140 through die bumps 120. The die 110, the die bumps 120, and the traces 140 are encapsulated by a mold 130. On a bottom surface of the substrate 160, LGA pads 170 are connected to the conductive vias 150, and solder 180 are connected to the LGA pads 170.

In FIG. 1B which illustrates the top view of the die package 100, the mold 130 is not shown for sake of convenience and clarity. From the top, the die 110 and the traces 140 are shown to be on the top surface of the substrate 160. The short dashed boxes within the traces 140 represent outlines of the conductive vias 150 within the substrate 160.

In FIG. 1C which illustrates the bottom view of the die package 100, the solder 180 is not shown for sake of convenience and clarity. From the bottom, the LGA pads 170 are shown to be on the bottom surface of the substrate 160. The short dashed boxes within the LGA pads 170 represent outlines of the conductive vias 150 within the substrate 160. Also, the large short dashed box in the center represents an outline of the die 110 on the opposite (top) surface of the substrate 160.

Note that the outer boundary of the conventional die package 100 is defined by the outer boundary of the substrate 160 and is well outside of the boundary of the conductive vias 150, and even outside of the boundary of the traces 140 and the LGA pads 170. This indicates that the layout area of the conventional die package 100 is substantial, i.e., the conventional die package 100 has a large footprint. This in turn indicates that less area is available for other components and can increase costs.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

An exemplary assembly for a device package is disclosed. The assembly may include a substrate and a through-substrate via extending from a top surface of the substrate to a bottom surface of the substrate. The assembly may also include a trace on the top surface of the substrate, and may be electrically coupled to the through-substrate via. The assembly may further include a contact pad on the bottom surface of the substrate. The contact pad may be electrically coupled to the through-substrate via. A sidewall of the through-substrate via may be exposed. At least a portion of the through-substrate via may be within an outer side boundary of the substrate. Also, the trace and the contact pad may be within the outer side boundary of the substrate.

An exemplary device package is disclosed. The device package may include a substrate, a through-substrate via extending from a top surface of the substrate to a bottom surface of the substrate, and a trace on the top surface of the substrate. The trace may be electrically coupled to the through-substrate via. The device package may also include a die above the substrate. The die may be encapsulated by a mold on the top surface of the substrate. The die may be electrically coupled to the trace. The device package may further include a contact pad on the bottom surface of the substrate. The contact pad may be electrically coupled to the through-substrate via. A sidewall of the through-substrate via may be exposed. At least a portion of the through-substrate via may be within an outer side boundary of the substrate. Also, the trace and the contact pad may be within the outer side boundary of the substrate.

An exemplary method of manufacturing a device package is disclosed. The method may comprise forming a substrate, forming a through-substrate via to extend from a top surface of the substrate to a bottom surface of the substrate, and forming a trace on the top surface of the substrate to be electrically coupled to the through-substrate via. The method may also comprise locating a die above the substrate encapsulating the die with a mold on the top surface of the substrate. The die may be located so as to be electrically coupled to the trace. The method may further comprise forming a contact pad on the bottom surface of the substrate to be electrically coupled to the through-substrate via. The through-substrate via may be formed such that a sidewall of the through-substrate via is exposed, and at least a portion of the through-substrate via is within an outer side boundary of the substrate. The trace and the contact pad may be formed such that they are within the outer side boundary of the substrate.

### BRIEF DESCRIPTION OF THE DRAWINGS

The accompanying drawings are presented to aid in the description of examples of one or more aspects of the disclosed subject matter and are provided solely for illustration of the examples and not limitation thereof.

FIGS. 1A-1C illustrate different views of a conventional die package;

FIGS. 2A-2C illustrate different views of an example device package;

FIGS. 3A-3D illustrate examples of different stages of forming a device package;

FIG. 4 illustrates a flow chart of an example method of forming a device package; and

FIG. 5 illustrates examples of devices with a device assembly integrated therein.

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

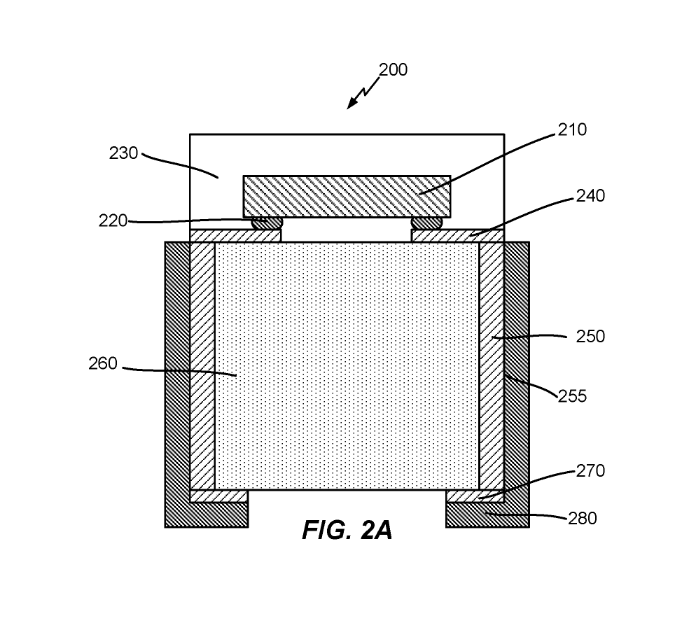

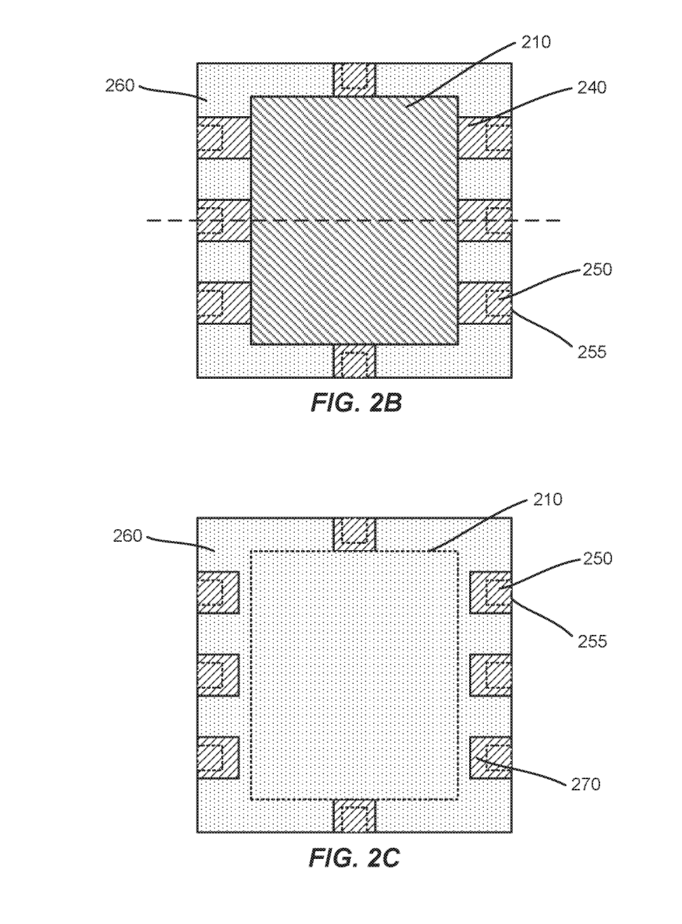

FIGS. 2A, 2B, and 2C respectively illustrate side, top, and bottom views of a device package 200 according to an aspect. The device package 200 may be a radio frequency (RF) module or other packaged semiconductor device modules. FIG. 2B shows a horizontal dashed line bisecting the device package 200. FIG. 2A may be viewed as illustrating a cross-sectional view of the device package 200 along the horizontal dashed line of FIG. 2B. As seen in these figures, the device package 200 may include a substrate 260 with one or more through-substrate vias (TSV) 250 formed therein. Each TSV 250 may be viewed as being an example of means for providing a through-substrate conduction. The TSVs 250 may be formed from conductive materials such as copper. Each TSV 250 may extend from a top surface to a bottom surface of the substrate 260.

Above the substrate 260, one or more traces 240 may be formed on the top surface of the substrate 260 to be electrically coupled to the TSVs 250. The traces 240 may be formed from conductive materials such as copper. A die 210 may be electrically coupled to the traces 240 through one or more die bumps 220. An example of the die 210 may be a semiconductor device. The die 210 including the die bumps 220 may be encapsulated by a mold 230. The mold 230, which may be formed on the top surface of the substrate 260, may also encapsulate the traces 240.

Below the substrate 260, one or more contact pads 270 may be formed on the bottom surface of the substrate 260 to be electrically coupled with the TSVs 250. The contact pads 270 may be LGA pads, and may be formed from conductive materials such as copper. Conductive joints 280, or simply joints 280, may be electrically coupled with the contact pads 270. For example, the joints 280, which may be solder pads, may be formed on the bottom surface of the contact pads 270. In this way, the die 210 may be electrically coupled to the joints 280 through the die bumps 220, the traces 240, the TSVs 250, and the contact pads 270. Some of the contact pads 270 may be signal pads configured to carry electrical signals from/to the die 210. Some others of the contact pads 270 may be power pads configured to provide supply voltage/ground to the die 210.

It should be noted that the combination of the substrate 260, the TSVs 250, the traces 240, and the contact pads 270 may be referred to as an assembly for the device package 200 in a sense that the assembly may be provided separately. For example, the device package 200 may be formed by attaching the die 210 to the assembly on top and attaching the assembly to a structure (e.g., PCB) on the bottom through the joints 280. That is, in an aspect, the assembly may be manufactured apart from other components of the completed device package 200.

As indicated, FIG. 2B illustrates the top view of the device package 200. For sake of convenience and clarity, the mold 230 is not shown. From this view, it is seen that the die 210 and the traces 240 may be formed to be on the top surface of the substrate 260. The short dashed boxes within the traces 240 may represent outlines of the TSVs 250 within the substrate 260.

Also as indicated, FIG. 2C illustrates the bottom view of the device package 200. Again for sake of convenience and clarity, the joints 280 are not illustrated. From this view, it is seen that the contact pads 270 may be formed to be on the bottom surface of the substrate 260. The short dashed boxes within the contact pads 270 may represent outlines of the TSVs 250 within the substrate 260. Also, the large short dashed box in the center may represent an outline of the die 210 on the opposite (top) surface of the substrate 260.

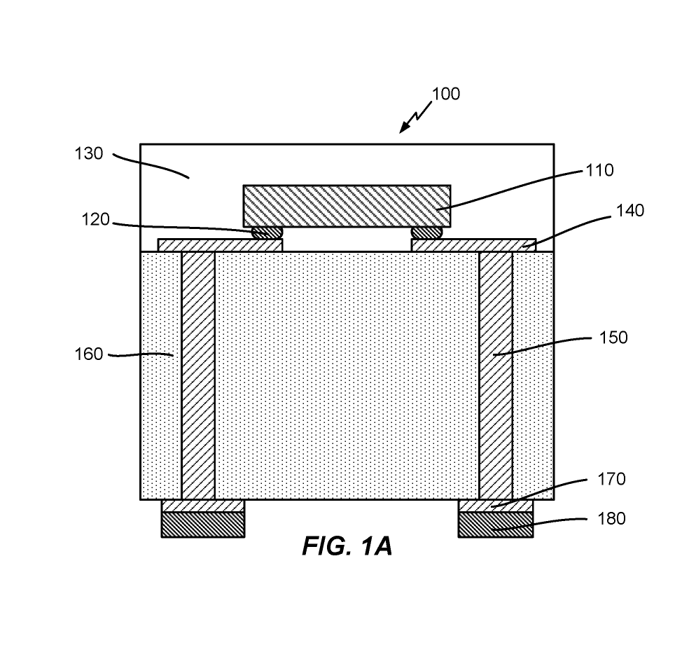

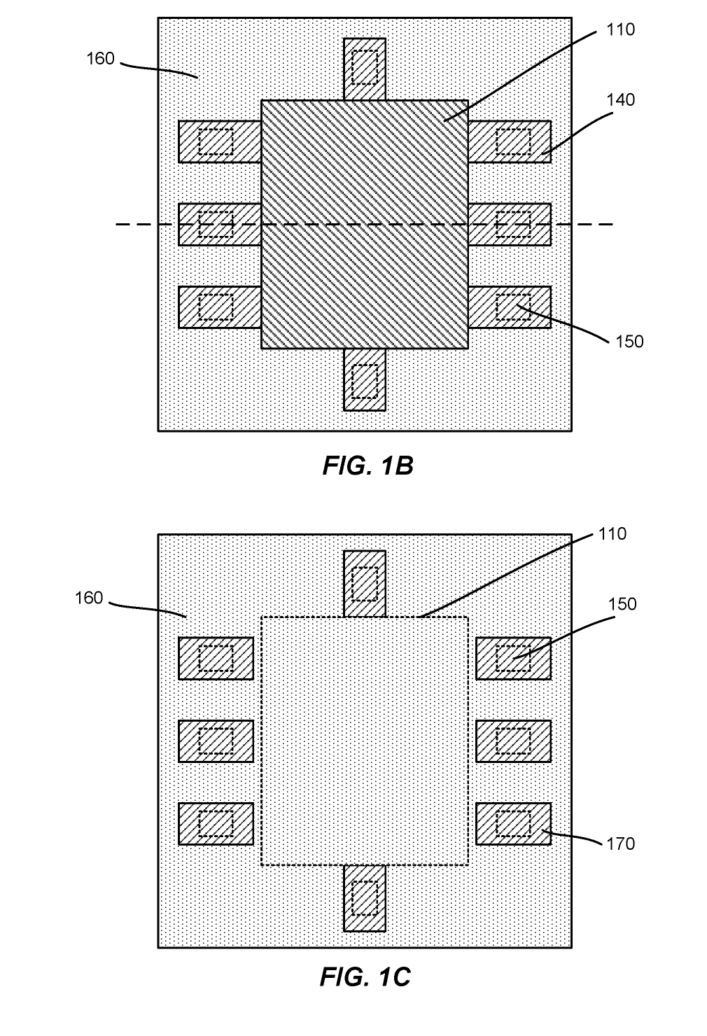

One difference (of which there can be several) between the device package 200 and the conventional die package 100 is that the device package 200 can be made to have a smaller footprint than the conventional die package 100. Recall that the outer boundary of the conventional die package 100 is well outside of the boundary defined by the conductive vias 150, the traces 140, or by the LGA pads 170. As seen in FIGS. 1A-1C, the outer boundary of the conventional die package 100 is defined by the outer boundary of the substrate 160. As seen in these figures, the traces 140, the conductive vias 150, the LGA pads 170, and even the solder 180 are entirely inside of the boundary defined by the substrate 160.

The device package 200 illustrated in FIGS. 2A-2C may have a smaller footprint, i.e., may occupy a smaller layout area than the conventional die package 100. But at the same time, the device package 200 can also maintain pin-to-pin compatibility with the conventional die package 100. For example, the locations of the contact pads 270 (see FIG. 2C) and the LGA pads 170 (see FIG. 1C) may be compatible.

The pin-to-pin compatibility means that the conventional die package 100 may be replaced with the device package 200 and no functionality would be lost. This can be an important consideration when manufacturing a device such as a smart phone. An individual component of the smart phone such as a RF module may be supplied by multiple vendors. By providing a compatible component that has advantages such as lower real estate foot print and/or reduce costs, a vendor may gain a competitive advantage.

In an aspect, the smaller footprint while maintaining the pin-to-pin compatibility may be achieved by reducing the outer boundary of the device package 200. Referring back to FIGS. 2B and 2C, the outer boundary of the device package 200 may still be defined by the outer boundary of the substrate 260. Also, at least portions of the traces 240, the contact pads 270, and the TSVs 250 may be within the outer boundary of the substrate 260.

But unlike the conventional die package 100 in which the conductive vias 150 are enclosed entirely within the substrate 160, the device package 200 may be such that the outer boundary of the substrate 260 need not be any larger than the boundaries defined by the TSVs 250, the traces 240, and/or the contact pads 270. For example, the device package 200 may be cut so as to expose sidewalls 255 of the TSVs 250. As seen in FIGS. 2B and 2C, on each side of the device package 200, the sidewalls 255 may be substantially coplanar with a plane defined by the side surface of the substrate 260. Similarly, the traces 240 and/or the contact pads 270 may be coplanar as well. In this way, the footprint of the device package 200 can be made to be substantially smaller.

As illustrated in FIG. 2A, recall that the joints 280 may be formed on the bottom surface of the substrate 250 to be electrically coupled with the TSVs 250 through the contact pads 270. FIG. 2A also illustrates that the joints 280 may be electrically coupled to the TSV 250 more directly. For example, the joints 280 may be formed on, e.g., in contact with, the sidewalls 255 of the TSVs 250. Note that the joints 280 may extend from the contact pads 270 and extend towards the top surface of the substrate 260.

However, this is optional, i.e., it is not necessary for the joints 280 to be formed on the sidewalls 255 of the TSVs 250. Also, the amount of the sidewall 255 exposed or covered by the joint 280 for each TSV 250 may be individualized. In other words, for each TSV 250, some, all or none of the sidewall 255 of that TSV 250 may be in contact with the joint 280 (not shown). This means that a vertical portion of one joint 280 need not be at a same height as a vertical portion of another joint 280. Note that even with joints 280 being formed on the sidewalls 255, the footprint of the device package 200 can still be smaller than the conventional die package 100.

While the joints 280 on the sidewalls 255 are optional, there can be some advantages. Recall that with the conventional die package 100, the conductive vias 150 are entirely within the boundary defined by the substrate 160. Therefore, the substrate 160 can provide a measure of mechanical support. But also recall that with the example device package 200, the sidewalls 255 of the TSVs 250 may be exposed. As a result, less support may be provided.

However, by forming the joints 280 on the sidewalls 255, the mechanical integrity of the device package 200 may be enhanced. Thus, the joints 280 may be viewed as being examples of means for providing conductance with support. In addition, the electrical conductivity and/or the thermal conductivity may be enhanced by the joints 280 formed on the sidewalls 255 of the TSVs 250. Even with the joints 280 formed on the sidewalls 255, the footprint of the device package 200 can still be less than the conventional die package 100.

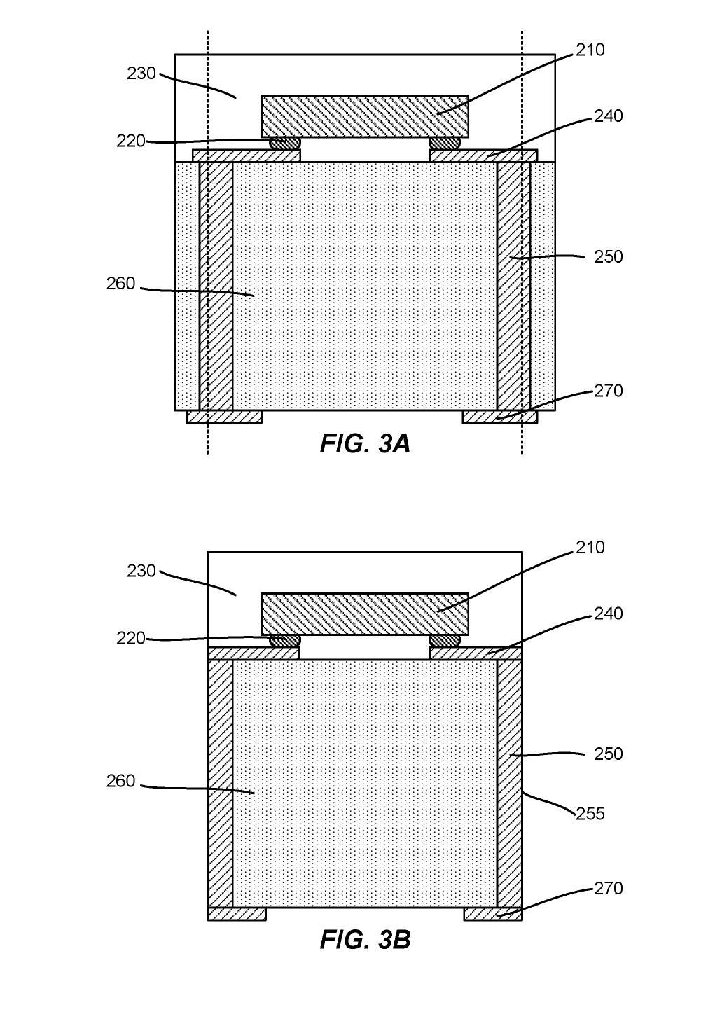

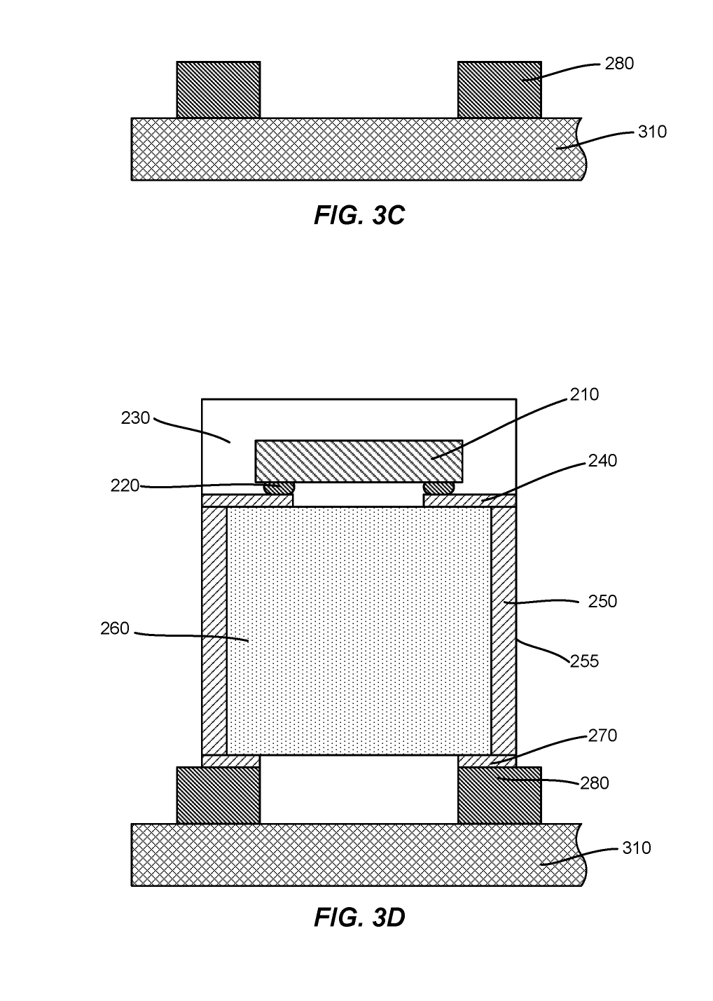

FIGS. 3A-3D illustrate examples of different stages of forming a device package such as the device package 200. FIG. 3A illustrates a stage in forming an assembly incorporated with the die 210. For ease of reference, the package illustrated in FIG. 3A will be referred to as a first stage package. As seen, the substrate 260 may be formed. Within the substrate 260, one or more TSVs 250 may be formed to extend from the top surface to the bottom surface of the substrate 260. For example, one or more vias may be drilled in the substrate 260, and the vias may be filled with conductive materials such as copper. Also, the substrate 260 and the TSVs 250 may be planarized such that the top surfaces of the substrate 260 and the TSVs 250 are coplanar and/or the bottom surfaces of the substrate 260 and the TSVs 250 are coplanar. Above the substrate 260, conductive materials such as copper may be used to form one or more traces 240 on the top surface of the substrate 260 and electrically coupled to the TSVs 250. The die 210 may be located above the substrate 260 so as to be electrically coupled to the traces 240 through one or more die bumps 220. The die 210 may be encapsulated with the mold 230 formed on the top surface of the substrate 260. Below the substrate 260, conductive materials such as copper may be used to form one or more contact pads 270 on the bottom surface of the substrate 260 so as to be electrically coupled with the TSVs 250.

The first stage package illustrated in FIG. 3A may be similar to the conventional die package 100 in the following sense. In the first stage package, the TSVs 250 may be entirely within the substrate 260. Also, the traces 240 and/or the contact pads 270 may also be entirely within an outer boundary defined by the substrate 260.

FIG. 3B illustrates a subsequent stage in which the device package is cut along cut lines. For ease of reference, the package illustrated in FIG. 3B will be referred to as a second stage package. The cut lines, which are illustrated in FIG. 3A as vertical dashed lines, can effectively define the outer boundary of the second stage package, which is the package after the cut. The cut lines may be chosen such that after the cut, the side walls 255 of the TSVs 250 are exposed. The cut lines may be coincident with the sidewalls 255 after the cut. Also after the cut, the TSVs 250, the traces 240, and/or the contact pads 270 may be within the outer boundary of the substrate 260 (e.g., see FIGS. 2B, 2C).

In FIG. 3A, the cut lines are inside the TSVs 250. This indicate that the cutting process may result in thinning the cross-sectional area of the TSVs 250. However, this is not a requirement. In an aspect, the cut lines can be chosen to coincide with the edges of the TSVs 250 if the exposed sidewalls 255 may be created by the cutting process.

FIG. 3C illustrates a stage in which one or more joint compounds 380 are prepared on a board 310. At this stage, the joints 280 may be solder paste. The board 310 may be a printed circuit board (PCB) or a carrier with a suitable surface. The carrier may be temporary (i.e., removable after the processing completes) or permanent (i.e., becomes a part of the finished device package). The stage illustrated in FIG. 3C may be performed independently of the stages illustrated in FIGS. 3A and 3B.

FIG. 3D illustrates a stage in which the second stage package of FIG. 3B is placed on the prepared board 310 of FIG. 3C. For ease of reference, the package illustrated in FIG. 3D will be referred to as a third stage package. Heat may be applied to the third stage package so that a reflow process (e.g., solder reflow) may be initiated. In this way, the joints 280 may be permanently attached to at least the bottom surfaces of the contact pads 270 resulting in the device package 200 illustrated in FIGS. 2A-2C.

Recall that for any particular TSV 250, the corresponding joint 280 may be formed on some, none, or all of the sidewall 255 of that TSV 250. In an aspect, the reflow process used to attach the joints 280 to the bottom surfaces of the contact pads 270 may also be used to form the vertical portions of the joints 280 on the sidewalls 255. Factors such as amount of solder paste on the board 310, solder paste compounds, temperature, and so on may be controlled to control an amount of wicking that may occur, which in turn may determine an amount of the vertical portions of the joints being formed on the sidewalls 255.

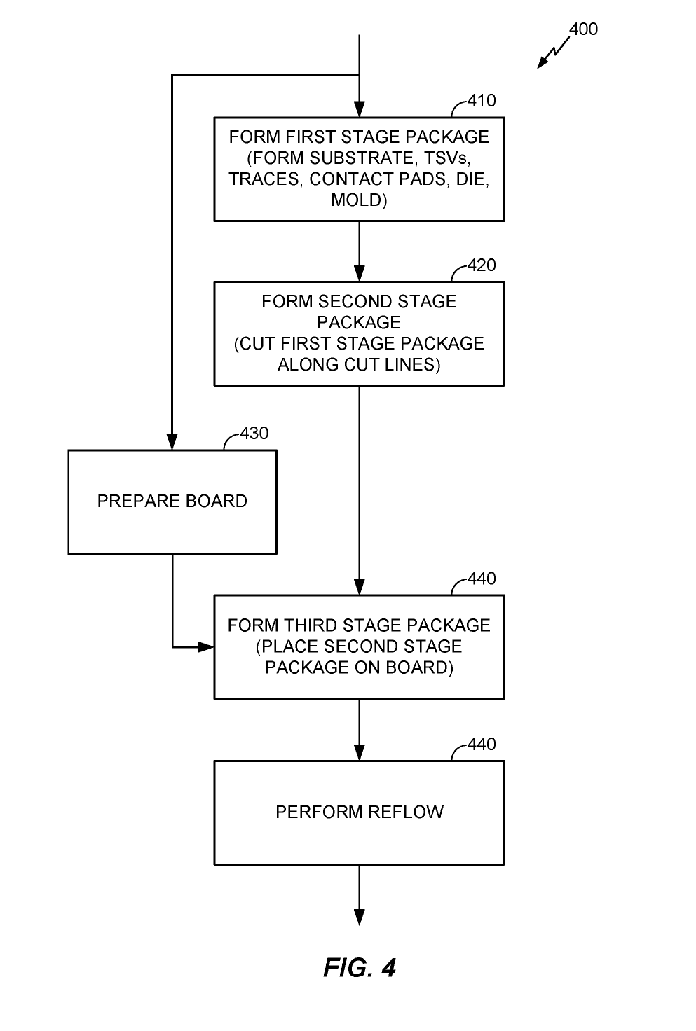

FIG. 4 illustrates a flow chart of an example method 400 of forming a device package such as the device package 200. It should be noted that not all illustrated blocks of FIG. 4 need to be performed, i.e., some blocks may be optional. Also, the numerical references to the blocks of the FIG. 4 should not be taken as requiring that the blocks should be performed in a certain order.

In block 410, the first stage package may be formed as illustrated in FIG. 3A. That is, the substrate 260 with the TSVs 250 may be formed, the traces 240 and the contact pads 270 may be formed on the top and bottom surfaces of the substrate 260, and the die 210 encapsulated by the mold 230 may be formed above the top surface of the substrate 260. In block 420, the first stage package may be cut along the cut lines to form the second stage package as illustrated in FIG. 3B. In block 430, the board 310 may be prepared, e.g., with solder paste, as illustrated in FIG. 3C. In block 440, the third stage package may be formed as illustrated in FIG. 3D. That is, the second stage package may be placed on the prepared board. In block 450, the reflow process may be performed. In an aspect, the reflow process may form the joints 280 on the bottom surfaces of the contact pads 270. Alternatively or in addition thereto, the reflow process may form the joints 280 on the sidewalls 255 of the TSVs.

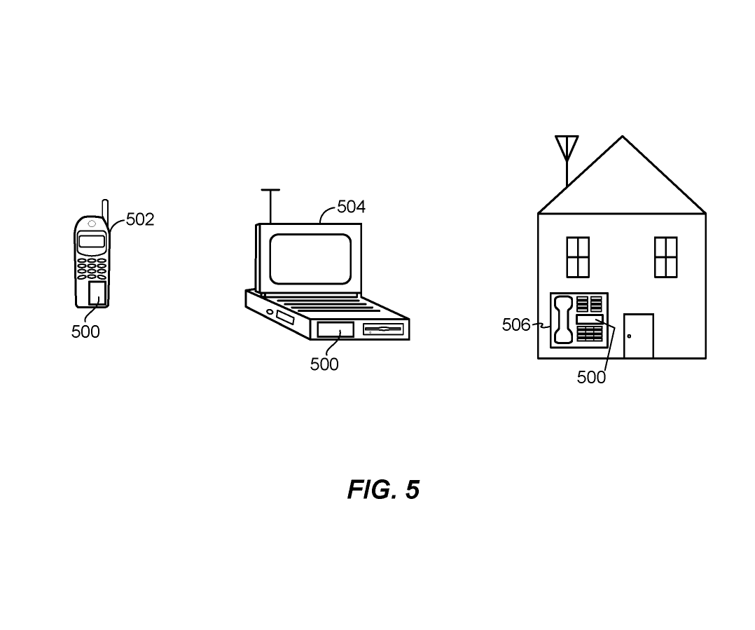

FIG. 5 illustrates various electronic devices that may be integrated with any of the aforementioned device package. For example, a mobile phone device 502, a laptop computer device 504, and a fixed location terminal device 506 may include a device package 500 as described herein. The device package 500 may be, for example, any of the integrated circuits, dies, integrated devices, integrated die packages, integrated circuit devices, die packages, integrated circuit (IC) packages, package-on-package devices described herein. The devices 502, 504, 505 illustrated in FIG. 5 are merely exemplary. Other electronic devices may also feature the device package 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2A-2C, 3, 4 and/or 5 may be rearranged and/or combined into a single component, process, feature or function or embodied in several components, processes, or functions. Additional elements, components, processes, and/or functions may also be added without departing from the disclosure. It should also be noted that FIGS. 2A-2C, 3, 4 and/or 5 and its corresponding description in the present disclosure is not limited to dies and/or ICs. In some implementations, FIGS. 2A-2C, 3, 4 and/or 5 and its corresponding description may be used to manufacture, create, provide, and/or produce integrated devices. In some implementations, a device may include a die, an integrated device, a die package, an integrated circuit (IC), an integrated circuit (IC) package, a wafer, a package on package (PoP) device, and/or an interposer.

The following is a non-exhaustive list of benefits:
The sidewalls 255 and/or the contact pads 270 may be used as pads for the joints 280;
The sidewalls 255 and/or the contact pads 270 may serve either as ground ports or signal ports;
Costs may be reduced by saving the layout area, as the signal paths are shifted to the boundary of the device package 200;
The device package 200 may be compatible with sidewall+bottom LGA pad package in low temperature co-fired ceramic (LTCC) modules; and
The device package 200 may be pin-to-pin compatible with existing conventional die packages 100 while reducing the layout area.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

While the foregoing disclosure shows illustrative embodiments, it should be noted that various changes and modifications could be made herein without departing from the scope of the disclosure as defined by the appended claims. The functions, steps and/or actions of the method claims in accordance with the embodiments described herein need not be performed in any particular order. Furthermore, although elements may be described or claimed in the singular, the plural is contemplated unless limitation to the singular is explicitly stated.

1. An assembly for a device package, comprising:
a substrate;
a through-substrate via (TSV) extending from a top surface of the substrate to a bottom surface of the substrate; and
a trace on the top surface of the substrate and configured to electrically couple to a contact pad on the bottom surface of the substrate, wherein the trace and the contact pad are electrically coupled together through the TSV,
wherein a sidewall of the TSV is not covered by the substrate,
wherein at least a portion of the TSV is within an outer side boundary of the substrate, and
wherein the trace and the contact pad are within the outer side boundary of the substrate.

2. The assembly of claim 1, wherein the sidewall of the TSV is substantially coplanar with a plane defined by a side surface of the substrate.

3. The assembly of claim 1, further comprising a joint on a bottom surface of the contact pad such that the joint is configured to electrically couple to the contact pad.

4. The assembly of claim 3, wherein the joint extends from the contact pad towards the top surface of the substrate on the sidewall of the TSV such that the joint is also configured to electrically couple to the TSV.

5. The assembly of claim 1, further comprising a joint on the sidewall of the TSV such that the joint is configured to electrically couple to the TSV.

6. A device package, comprising:
a substrate;
a through-substrate via (TSV) extending from a top surface of the substrate to a bottom surface of the substrate;
a trace on the top surface of the substrate and configured to electrically couple to a contact pad on the bottom surface of the substrate, wherein the trace and the contact pad are electrically coupled together through the TSV;
a die above the substrate and configured to electrically couple to the trace; and
a mold on the top surface of the substrate and encapsulating the die,
wherein a sidewall of the TSV is not covered by the substrate,
wherein at least a portion of the TSV is within an outer side boundary of the substrate, and
wherein the trace and the contact pad are within the outer side boundary of the substrate.

7. The device package of claim 6, wherein the sidewall of the TSV is substantially coplanar with a plane defined by a side surface of the substrate.

8. The device package of claim 6, further comprising a joint on a bottom surface of the contact pad such that the joint is configured to electrically couple to the contact pad.

9. The device package of claim 8, wherein the joint extends from the contact pad towards the top surface of the substrate on the sidewall of the TSV such that the joint is also configured to electrically couple to the TSV.

10. The device package of claim 6, further comprising a joint on the sidewall of the TSV such that the joint is configured to electrically couple to the TSV.

11. The device package of claim 6, wherein the die is within the outer side boundary of the substrate.

12-20. (canceled)

21. An assembly for a device package, comprising:
a substrate;
means for providing a through-substrate conduction extending from a top surface of the substrate to a bottom surface of the substrate; and
a trace on the top surface of the substrate and configured to electrically couple to a contact pad on the bottom surface of the substrate, wherein the trace and the contact pad are electrically coupled together through the means for providing the through-substrate conduction,
wherein a sidewall of the means for providing the through-substrate conduction is not covered by the substrate,
wherein at least a portion of the means for providing the through-substrate conduction is within an outer side boundary of the substrate, and
wherein the trace and the contact pad are within the outer side boundary of the substrate.

22. The assembly of claim 4, wherein the joint is in contact with an entire height of the sidewall of the TSV.

23. The device package of claim 9, wherein the joint is in contact with an entire height of the sidewall of the TSV.

24. The device package of claim 10, wherein the joint is in contact with an entire height of the sidewall of the TSV.

25. The assembly of claim 4, further comprising:
a joint on a bottom surface of the contact pad such that the joint is configured to electrically couple to the contact pad,
wherein the joint extends from the contact pad towards the top surface of the substrate on and in contact with an entire height of the sidewall of the means for providing the through-substrate conduction such that the joint is also configured to electrically couple to the means for providing the through-substrate conduction.

26. The device package of claim 6,
wherein the die comprises die bumps on a lower surface of the die, and
wherein the trace is electrically coupled to the die through the die bumps.
